(19) United States
(12) Patent Application Publication
(10) Pub. No.: US 2026/0003007 A1
(43) Pub. Date: Jan. 1, 2026

(54) STATE OF CHARGE LIMITATION FOR INCREASING BATTERY LIFE

(71) Applicant: NIVALIS ENERGY SYSTEMS LLC, HUNT VALLEY, MD (US)

(72) Inventors: Ryan KEMMET, Phoenix, AZ (US); Samuel PLUNKETT, Chicago, IL (US); Justin LESNIAK, Milford, MI (US)

(73) Assignee: NIVALIS ENERGY SYSTEMS LLC, HUNT VALLEY, MD (US)

(21) Appl. No.: 18/756,378

(22) Filed: Jun. 27, 2024

(51) Int. Cl. G01R 31/396; G01R 31/36; G01R 31/367

(52) U.S. Cl. CPC G01R 31/396; G01R 31/3647; G01R 31/367

(57) ABSTRACT

A method and system for intelligent and variable charging of a power supply for a transport refrigeration unit (“TRU”) installed on a transport. The method and system varies a daily state of charge or total battery capacity based upon expected TRU need. The system includes at least one battery and a charging connector for an EV vehicle charger. A controller controls a charge level of the at least one battery. The controller has a location and/or a travel route for the TRU and access external weather data for that location or route. The controller analyzes a weather pattern for the location and/or the travel route to determine an expected environment, and determines the battery capacity required and maximum state of charge for the battery system based upon the expected environment. The system charges the at least one battery via the charging connector to obtain the maximum state of charge.

### TECHNICAL FIELD

The present disclosure relates generally to the field of transport refrigeration systems and methods of operating the same, and more particularly to a state of charge (“SOC”) limitation based on, for example, one or more of weather and duty cycle information for increasing the life of one or more batteries in battery powered refrigerated trailers.

### BACKGROUND

Refrigeration trucks and trailers provide an effective means of long-distance transport for perishable goods. Power requirements for maintaining the perishable load may encompass one or more of a compressor for circulating refrigerant, a fan for circulation of temperature-controlled air, a condenser, an evaporator, and an expansion valve. A transport refrigeration unit (“TRU”) system may be attached to the front of a trailer for maintaining controlled temperatures during transport. Typically, a TRU may be powered by a small diesel engine that is integral with the refrigeration system on the trailer. Many trailers are fitted with hybrid TRUs that allow for a switch between diesel and electric modes. In diesel mode, the small diesel engine may power an AC motor, which in turn powers a compressor, or it may be directly coupled to the compressor (i.e., mechanically connected). In electric mode, the AC motor may be powered by an electric source, such as one or more batteries and/or a utility source (i.e., “shore power”). More recently, fully electric TRUs have become more common. There is a continuing need to improve battery-based electric TRUs.

### SUMMARY

Limiting the range of used battery capacity generally increases the life of battery for many reasons including increasing plating reactions at high states of charge. In normal operation the primary energy requirement in a refrigerated trailer is the heat flowing from the outside of the trailer into the trailer. In other words, the difference between the ambient temperature and the internal trailer set point. In embodiments of this invention, the day ahead weather forecast is used to determine the required battery capacity and/or set the maximum charging set point on the battery and/or add battery capacity. When the weather is cooler, the energy needed throughout the day will be less and the maximum charging point can be reduced, on warmer days the energy needed will be more and the maximum charging point can be increased and/or additional batteries can be added to increase capacity. Instead of always charging to the maximum amount (hottest days of the year) the maximum charge can be reduced and/or batteries can be removed for cooler days to increase the life of the battery and/or increase carrying capacity of the trailer. GPS can be used for accurate location data.

In embodiments, a controller records daily usage and duty cycle information from operation of the particular system in the field. Using historical data on a particular unit, the controller predicts the operational needs for electricity needed for the next day and sets the maximum state of charge to charge enough for the operating with some margin.

In depth analysis is possible using time of year (type of product being used) and geography (GPS). Combining prior temperature information and duty cycle information together produces a more accurate expected energy use. In embodiments, similar prior temperatures are grouped to compare use on those days. Likewise similar times of year can be grouped. The system can combine geographic information, projected temperature, and calendar days with previous uses.

The invention includes a method of charging a battery system for a transport refrigeration unit (“TRU”) installed on a transport. The method includes: determining a location and/or a travel route for the TRU; analyzing a weather pattern for the location and/or the travel route to determine an expected environment; determining battery capacity required and/or a maximum state of charge for the battery system as a function of the expected environment; and charging the battery system with a power supply to obtain the maximum state of charge. The battery capacity required and/or the maximum state of charge is desirably determined as a function of a time at the location and/or the travel before reaching a next power supply.

Weather patterns can be downloaded as forecast data from a weather service. The battery capacity required and/or the maximum state of charge can be determined by comparing the weather pattern to historical weather patterns and battery use for the TRU.

In embodiments, the method further includes: determining a thermal loss quotient for the transport; and determining the battery capacity required and/or the maximum state of charge for the battery system as a function of the expected environment and the thermal loss quotient. The thermal loss quotient can be determined from a cooling system coefficient of performance and/or transport information selected from transport volume, transport insulation value, and transport door type. A baseline thermal loss quotient can be established for the transport. A cooling efficiency of the TRU can be determined over time. The baseline thermal loss quotient can be adjusted based upon the determined cooling efficiency.

The batteries are typically charged using an electric vehicle charger. In embodiments, the transport vehicle generates addition power during use, and an expected power generation by an onboard vehicle power system can be taken into account and used to adjust the maximum state of charge for the expected power generation.

In embodiments, battery capacity is changed by the addition or removal of battery modules from the battery system. The actual battery usage can be recorded and an analysis can be used to predict maximum daily battery usage over a time frame, such as seasons or longer periods of time. In embodiments, the historic battery usage and predicted battery usage for a particular system is used to change the battery capacity in alternative means, such as removing or adding additional battery modules. Adding or removing battery capacity through the addition or removal of battery modules ensures that only the weight of batteries that are required is on the vehicle, thus optimizing carrying capacity of the vehicle. Batteries can be added when needed, and higher energy density batteries with shorter life spans may be utilized to provide the battery capacity when more capacity without a significant weight penalty.

The invention further includes a method of charging a battery system for a TRU, including steps of: determining a thermal loss quotient for the TRU; analyzing a weather pattern for a location and/or a travel route to determine an expected environment for the transport; determining the battery capacity required and/or a maximum state of charge for the battery system as a function of the thermal loss quotient and the expected environment; and charging the battery system with a power supply to obtain the maximum state of charge. The thermal loss quotient can be determined from heat rise over a period of time and/or energy input required to maintain a steady transport temperature.

In embodiments, determining the battery capacity required and/or the maximum state of charge is done as a function of a transport temperature need and estimated operation time, such as one operational period (e.g., one day), or a 6-16 hour operational period.

The invention further includes a power system for a TRU. The power system includes at least one battery and a charging connector (e.g., an EV connector) in electrical supply combination with the at least one battery. A controller in combination with the charging connector controls a charge level of the at least one battery. The controller includes or is in combination with a network connection adapted to connect with transport systems and external weather data. The controller is configured to determine a location and/or a travel route for the TRU, analyze a weather pattern for the location and/or the travel route to determine an expected environment, determine the battery capacity required and/or a maximum state of charge for the battery system as a function of the expected environment, and charge the at least one battery via the charging connector to obtain the maximum state of charge. The battery capacity required and/or maximum state of charge can be determined as a function of a time at the location and/or the travel before reaching a next power supply.

In embodiments, the transport operator is notified to change the amount of batteries in the battery system. The controller can issue an alert or recommendation through the network connection, such as to a computer system or device of the operator.

In embodiments, the controller includes a predetermined thermal loss quotient for the transport, and determines the battery energy required and/or maximum state of charge for the battery system as a function of the expected environment and the thermal loss quotient.

### BRIEF DESCRIPTION OF DRAWINGS

Other objects and advantages of the present disclosure will become apparent to those skilled in the art upon reading the following detailed description of exemplary embodiments and appended claims, in conjunction with the accompanying drawings, in which like reference numerals have been used to designate like elements.

FIG. 1 is a diagram illustrating an exemplary transport refrigeration unit (TRU) and power supply system, according to an embodiment of the present disclosure.

FIG. 2 is an overall system diagram of an example power supply system, according to an example of the present disclosure.

FIG. 3 is a flowchart illustrating a method of using weather information to set a maximum SOC for one or more batteries, according to an example of the present disclosure.

FIG. 4 is a flowchart illustrating a method of using prior usage data to set a maximum SOC for the one or more batteries, according to an example of the present disclosure.

FIG. 5 is a flowchart illustrating a method of setting a baseline for a transport and TRU, according to an example of the present disclosure.

FIG. 6 is a functional block diagram of a machine in the example form of computer system within which a set of instructions for causing the machine to perform any one or more of the methodologies, processes or functions discussed herein may be executed, according to an example of the present disclosure.

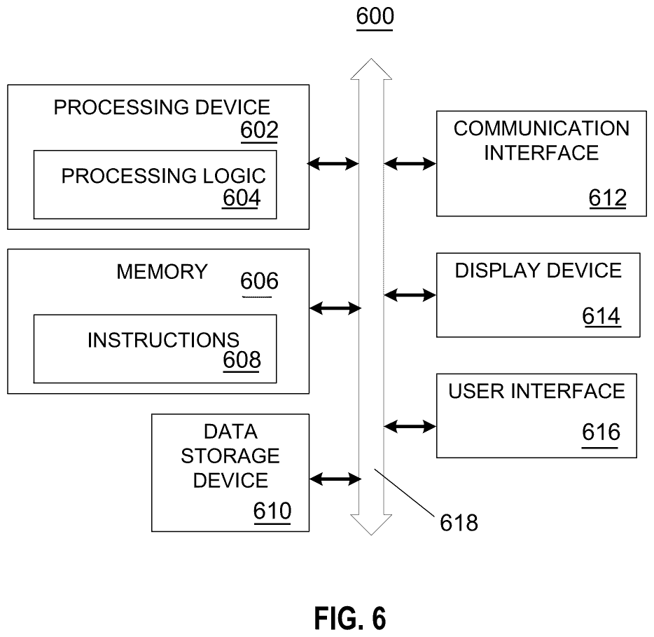

The figures are for purposes of illustrating example embodiments, but it is understood that the inventions are not limited to the arrangements and instrumentality shown in the drawings. In the figures, identical reference numbers identify at least generally similar elements.

### DETAILED DESCRIPTION

The present disclosure describes systems, methods, and apparatuses configured to provide a state of charge (“SOC”) limitation based on, for example, one or more of weather and duty cycle information for increasing the life of one or more batteries in battery powered refrigerated trailers.

The present disclosure will now be described more fully hereinafter with reference to the accompanying drawings, which form a part hereof, and which show, by way of non-limiting illustration, certain examples. Subject matter may, however, be described in a variety of different forms and, therefore, covered or claimed subject matter is intended to be construed as not being limited to any examples set forth herein. Among other things, subject matter may be described as methods, devices, components, or systems. Accordingly, examples may take the form of hardware, software, firmware or any combination thereof (other than software per se). The following detailed description is, therefore, not intended to be taken in a limiting sense.

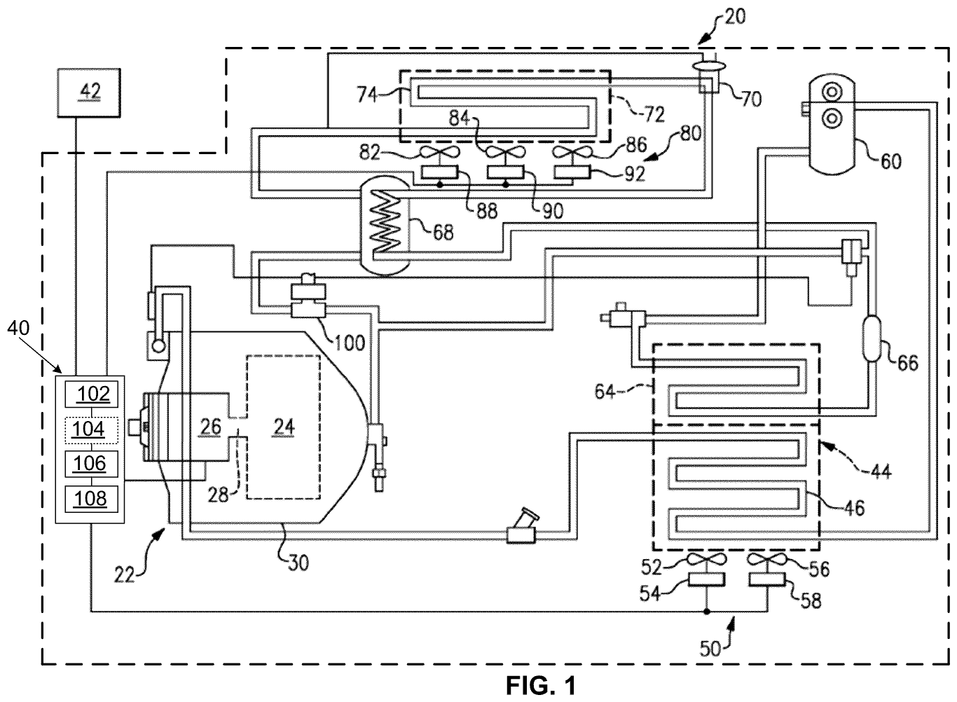

Referring now to FIG. 1, a diagram illustrating an exemplary transport refrigeration unit (“TRU”) 20 and one or more power supply systems 42 is shown. The TRU 20 shown in FIG. 1 is meant for illustrative purposes and is not intended to limit the present disclosure. Different configurations and components may be used for the TRU 20 and still fall within the scope of the present disclosure.

The TRU 20 may include a compressor system 22. The compressor system 22 may include a compressor 26, a compression chamber 24, and a compression mechanism. Optionally, the compressor system 22 may be sealed within a common housing 30. As used herein, the compressor 26 may include one or more of an AC motor, a compressor, a single unit comprising an AC motor and compressor, a fan, a condenser, an evaporator, and an expansion valve.

A power delivery system 40 may be connected to and/or incorporated within the TRU 20 and may be capable of driving the compressor 22 in one or more ways, as described below. The power delivery system 40 may also provide power to satisfy electrical requirements of other portions of the TRU 20. In an example, the power delivery system 40 may integrate one or more power supply systems 42 into the TRU 20 via, for example, an AC contactor 106 and may deliver power to the compressor via a compressor contactor 108. The power delivery system 40 may include a controller that may be used to control power usage in the TRU 20.

Refrigerant may enter the compressor 26 and may be compressed to a higher temperature and pressure. Refrigerant gas may then move into an air-cooled condenser 44. Air flowing across a group of condenser coil fins and tubes 46 may cool the gas to its saturation temperature. The air flow across the condenser 44 may be energized by a condenser fan assembly 50 having one or more fans. The illustrated example includes a fan 52, an electrical condenser fan motor 54, and a second fan 56 having an electrical motor 58. The controller within the power delivery system 40 may regulate power supply to one or more of the electrical condenser fan motor 54 and the electrical motor 58.

By removing latent heat, the gas may condense to a high pressure/high temperature liquid and flow to a receiver 60 that may provide storage for excess liquid refrigerant during low temperature operation. From the receiver 60, the liquid refrigerant may pass through a subcooler heat exchanger 64, through a filter dryer 66 that may keep the refrigerant cool and dry, then to a heat exchanger 68 that may increase the refrigerant subcooling, and then pass to a thermostatic expansion valve 70.

As the liquid refrigerant passes through the expansion valve 70, some of it may vaporize into a gas. Return air from the refrigerated space may flow over the heat transfer surface of an evaporator 72. As refrigerant flows through tubes 74 in the evaporator 72, the remaining liquid refrigerant may absorb heat from the return air, and in so doing, may be vaporized. The air flow across the evaporator may be energized by an evaporator fan assembly 80. The illustrated example includes a first fan 82, a second fan 84, and a third fan 86 that may be respectively powered by a first electric fan motor 88, a second electric fan motor 90, and a third electric fan motor 92. The first electric fan motor 88, the second electric fan motor 90, and the third electric fan motor 92 may receive their electrical power from at least one of the one or more power supply systems 42 and/or the power delivery system 40. The controller within the power control system 42 may control the consumption of power and operations of the first electric fan motor 88, the second electric fan motor 90, and the third electric fan motor 92 of the evaporator fan assembly.

Refrigerant vapor may flow through a suction modulation valve 100 back to the compressor system 22 and the compressor 26. A thermostatic expansion valve bulb or sensor may be located on the evaporator outlet tube. The bulb may control the thermostatic expansion valve 70, to control refrigerant super-heating at the evaporator outlet tubing.

In an example, the power delivery system 40 may include only an electric motor 102 directly mechanically coupled to the compressor 26. In another example, the power delivery system 40 may include a dedicated engine and internal generator (e.g., an internal combustion engine (“ICE”) system) 104 the electric motor 102. The ICE system 104 and/or the electric motor 102 may be directly mechanically coupled to the compressor 26. While the horsepower of the ICE system 104 may vary, in one example it is contemplated that the ICE system may have approximately 20 to approximately 25 horsepower, although higher horsepower ICE systems are contemplated. The electric motor 102 may be generally operable over a wide range of voltages (e.g., between 400 VAC 3 phase 50 Hz and).

If the power delivery system 40 includes the ICE system 104, it may also include an internal generator that is driven by the dedicated engine to produce an amount of power for the specific application. In an example, the internal generator may be a 120 volt AC generator capable of a power output of approximately 3 kW to approximately 3.5 kW. In another example, the internal generator may be an AC generator capable of producing approximately 327 VAC to approximately 537 VAC at up to 29 A (approximately 9.4 kW to approximately 15.6 kW). The internal generator may be coupled to the electric motor 102 and may be used to power one of more of the electric motor 102 and other electronics within the TRU 20 and on the vehicle itself.

Additionally, or alternatively, the electric motor 102 may be coupled to the one or more power supply systems 42. The one or more power supply systems 42 may include one or more of a main generator powered by the main engine of a vehicle connected to the trailer, one or more batteries, and shore power. The power delivery system 40 may be capable of switching (either manually or automatically) between one or more of the internal generator of the ICE system 104 and the one or more power supply systems 42, For example, the electric motor 102 may be powered by one of the one or more of the batteries, the internal generator of the ICE system 104, and the main generator while the trailer is moving and one of the one or more batteries, the internal generator of the ICE system 104, and the shore power when the trailer is stationary and plugged into an electrical connection. In an example, the electric motor 102 may completely bypass the ICE system 104 altogether, allowing the ICE system 104 to remain unused or be completely removed from the TRU 20 altogether.

Limiting the range of used capacity for the one or more batteries of the power supply system 42 may increase the life of the one or more batteries for many reasons. For example, plating reactions occur more easily/frequently at high states of charge and these reactions decrease the life of the one or more batteries.

In typical operation, the primary energy requirement for a TRU of a refrigerated trailer is countering heat energy that flows from outside of the trailer into the trailer (e.g., the difference between the ambient temperature and the internal trailer set point). For example, the warmer it is outside the trailer and the more frequently doors of the trailer are opened, the more energy it will take to cool the trailer to a determined temperature.

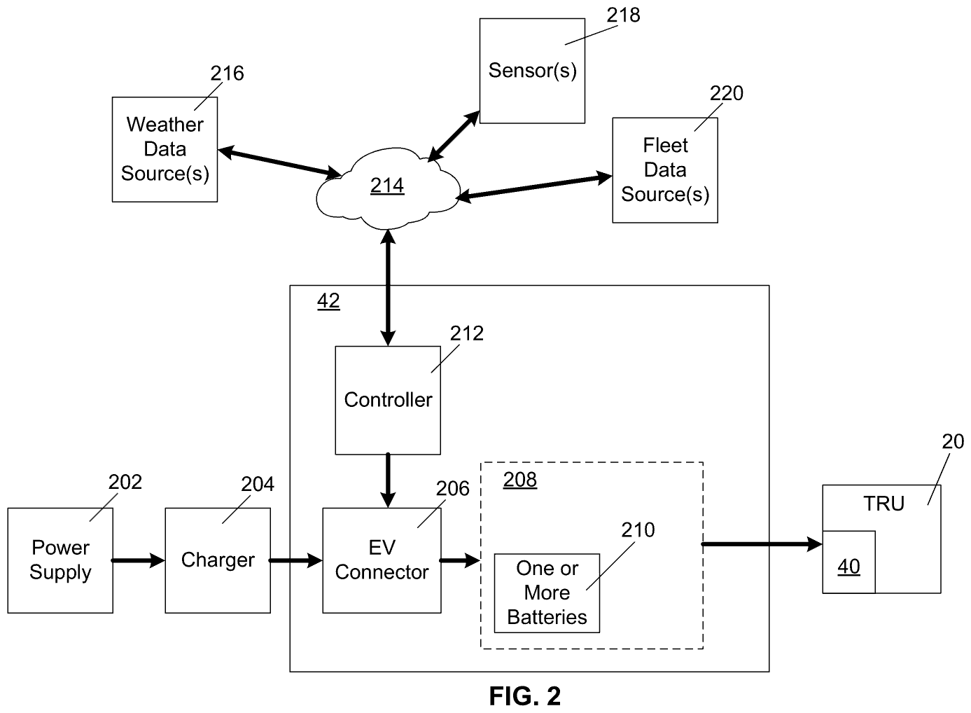

Referring now to FIG. 2, an overall system diagram of an example of the one or more power supply systems 42 is shown.

A power supply 202 may be connected to a charger 204. The power supply 202 may be any type of voltage. For example, the power supply 202 may be one or more of 440 VAC 3phase, 400 VAC 3 phase, 480 VAC 3 phase, 240 VAC single phase, and 120 VAC single phase. The charger 204 may be any type of charger (e.g., AC, DC, or AC/DC).

An electrical vehicle (“EV”) connector 206 may be used to connect the one or more power supply systems 42 to the charger 204. The EV connector 206 may be any connection (e.g., socket, plug, port) that is used to couple the power supply system 42 to the charger 204. For example, the EV connector 206 may be one or more of a SAE J1772 Type 1 connector, a Mennekes (Type 2) connector, CCS Type 1 connector (e.g., CCS1, CCS Combo 1, SAE J1772 Combo connector), a CCS Type 2 connector, a GB/T AC connector, a GB/T DC connector, a NACS connector, and a CHAdeMo connector.

The EV connector 206 may be coupled to one or more charging components 208, which may include one or more batteries 210. For the purposes of this disclosure, individual components (e.g., busses, inverters, circuit breakers, etc.) of the one or more charging components 208 are not shown. Any configuration of the one or more charging components is compatible with the present disclosure and any/all configurations are contemplated. In an example, the EV connector 206 may be directly coupled to the one or more batteries 210. In another example, the EV connector 206 may be coupled to one or more of the individual components of the one or more charging components 208. The one or more charging components 208 may take voltage delivered from the EV connector 206 and one or more of store, process, convert, step down/step up the voltage to deliver to the power delivery system 40 to power the TRU 20.

A controller 212, such as an engine control unit (ECU), a vehicle control unit (VCU), or charging control unit (CCU), may be coupled to the EV connector 206 and may determine one or more of the type and amount of voltage that is delivered from the charger 204 to the one or more batteries (i.e., the SOC of the one or more batteries 210) via the EV connector 206. Although shown as part of the one or more power supply systems 42, the controller 212 may be a separate component.

The controller 212 may be communicatively coupled to one or more weather data sources 216, one or more sensors 218, and one or more fleet data sources 220 via one or more networks 214. The one or more networks 214 may include, for example, a private network (e.g., a local area network (LAN), a wide area network (WAN), intranet, etc.) and/or a public network (e.g., the Internet).

The one or more weather data sources 214 may include, without being limited to, weather forecast model sources, one or more weather observations data sources associated with one or more locations and the like. In some examples, sources for weather forecast model(s) may provide weather model data for generating weather forecasts for one or more geographical regions. In one non-limiting example, the weather forecast model source(s) may include one or more of National Oceanic and Atmospheric Administration (NOAA) United States (US) Global Forecast System (GFS), NOAA GFS global ensemble (GFS ENS), NOAA GFS global ensemble Extension (GFS ENS EXT), NOAA's Climate Forecast System Ensemble model (CFS ENS), European Center for Medium-Range Weather Forecast (ECMWF), ECMWF Ensemble, ECMWF Ensemble Extension (ECMWF EXT), ECMWF Seasonal model (SEAS) and its corresponding extension model (SEAS EXT) and other gridded binary format (GRIB) weather forecast model source(s). In general, a weather forecast model source may run a weather forecast model (e.g., periodically such as quarterly, monthly, multiple times per week, one or more times per day, asynchronously, in response to a predetermined condition, etc.) and may provide weather forecast data for up to a predetermined number of days. For example, the model for the GFS is run four times a day and may produce forecasts for up to 16 days in advance and run, for example, four times per day. As another example, the CFS ENS may run daily and may forecast out nine months into the future. In one non-limiting example, source(s) for weather observations data may include one or more of Meteorological Aerodrome Report (METAR) data and Climate Forecast System (CFS) data including CFS Reanalysis (CFS-R) data for one or more locations (e.g., one or more airports, weather stations, etc.). In some examples, CFS-R data may be used to provide global observation estimates, for an even greater number of weather parameters, as estimates which METAR sensors and/or limited physical locations may not provide. In general, weather observations data may be updated periodically (e.g., hourly, daily, monthly, quarterly, etc.), and may include various weather data (e.g., temperature, dew point, wind direction, wind speed, precipitation, cloud cover, visibility, barometric pressure and the like, as well as derived values such as GWDD) for one or more weather observation locations. In general, the one or more weather data sources may include any suitable weather data sources for weather forecast model(s) and weather observations data associated with one or more locations. In general, the one or more weather data sources that may comprise a server computer, a desktop computer, a laptop, a smartphone, or any other electronic device known in the art configured to capture data, receive data, generate weather forecast model data, store data and/or disseminate any suitable weather data.

The one or more sensors 218 may include one or more temperature measurement devices (e.g., thermometers, thermocouples, etc.), one or more weather measurement devices (e.g., barometers, hygrometers, etc.) located within the trailer, outside the trailer, or both. The one or more sensors 218 may also include one or more devices configured to measure the SOC of the one or more batteries and/or voltage usage/stage of the one or more power deliver systems 42 and/or the TRU 20. The one or more sensors 218 may also include one or more GPS sensors.

The one or more fleet data sources 220 may include information about SOC, voltage usage, weather information, for one or more other vehicles in a fleet.

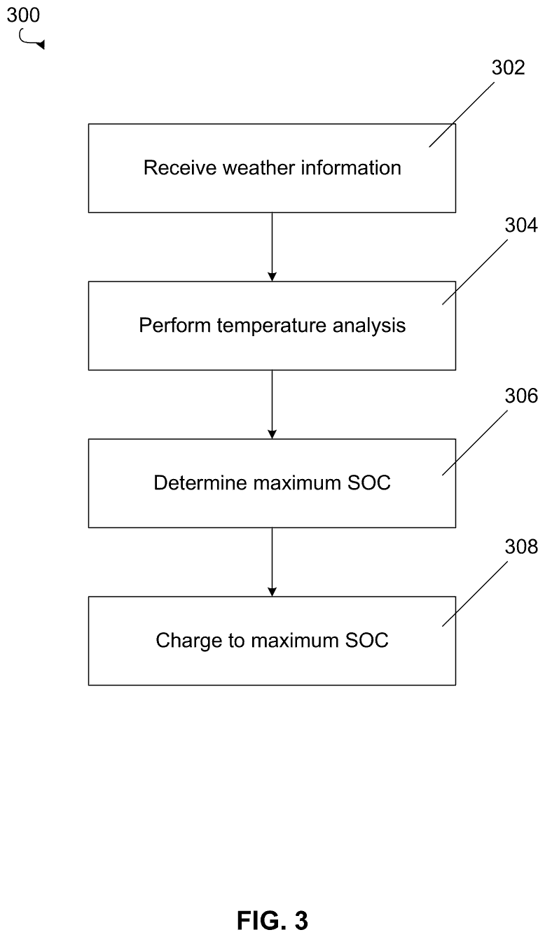

Referring now to FIG. 3, a flowchart 300 illustrating a method of using weather information to set a maximum SOC for the one or more batteries 210 is shown.

In an example, weather information is used to set a maximum charging set point on the one or more batteries to minimize over charging of the one or more batteries 210. For example, when the weather is cooler, the energy needed to cool the trailer throughout the day may be less and the maximum charging point may be reduced. On warmer days, the energy needed to cool the trailer may be more and the maximum charging point may be increased. Instead of always charging the one or more batteries 210 to the maximum amount each time, the maximum charge can be reduced for cooler days to increase the life of the one or more batteries 210.

In step 302, the controller 212 receives weather information from the one or more weather data sources 216. If the one or more sensors 218 include a GPS device, the controller 212 may use this device for accurate location data that can then be used to determine the applicable weather information.

In step 304, the controller 212 performs a temperature analysis to determine a maximum SOC of the one or more batteries 210 (i.e., a maximum amount of voltage that the EV connector 206 permits to be delivered to the one or more batteries 210). The maximum SOC may be determined by X times difference between a maximum operating ambient temperature (e.g., as determined by the one or more sensors 218) and a forecast temperature (e.g., received from the one or more weather data sources 216).

In step 306, the controller 212 may determine the maximum SOC of the one or more batteries 210. A required battery capacity can also optionally be determined in step 306. In step 308, the controller 212 may allow the EV connector 206 to deliver a maximum amount of voltage to the one or more batteries 210 to achieve a maximum SOC. Once the maximum SOC is achieved, the controller 212 may direct (e.g., deactivate) the EV connector 206 to stop delivering voltage to the one or more batteries 210. In an example, charging may cease. In another example, the EV connector 206 may direct any excess voltage to the other one or more charging components 208 such that no voltage is delivered to the one or more batteries 210. In an example, the one or more charging components 208 may direct the voltage to the power delivery system 40, thereby allowing the TRU 20 to operate while the charger 204 is connected.

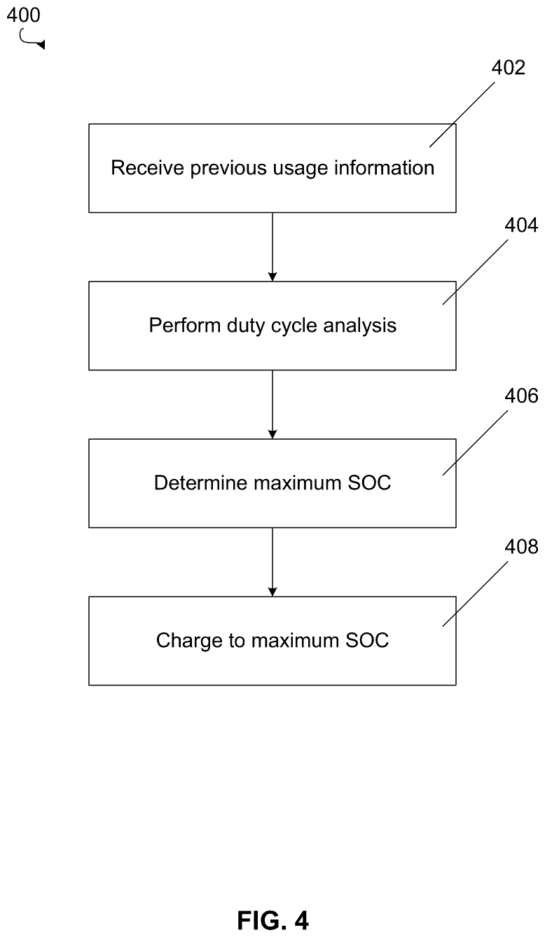

Referring now to FIG. 4, a flowchart 400 illustrating a method of using prior usage data to set a maximum SOC for the one or more batteries 210 is shown.

Additionally, or alternatively, usage and/or duty cycle information from operation of the refrigerated trailer (or any other number of refrigerated trailers in a fleet) in the field may be used to predict the operational needs and SOC needed for future use. The maximum SOC of the one or more batteries 210 may be set to be high enough for the predicted operating needs over the next operating cycle (e.g., with some margin).

In step 402, the controller 212 receives previous usage information. The previous usage information may be for the particular trailer and may be received by the one or more sensors 218. Additionally or alternatively, the previous usage information may be from one or more other vehicles in a fleet and may be received from the one or more fleet data sources 220. Further, the previous usage information may also include previous weather information from the one or more weather data sources 216. The previous weather information may be combined with location information received from a GPS device of the one or more sensors 218 along with the previous usage information to produce a more accurate expected energy use. For example, one or more of similar prior temperatures, similar times of year, and similar locations may be grouped to compare usage on those days.

In step 404, the controller 212 performs a duty cycle analysis to determine a maximum SOC of the one or more batteries 210 (i.e., a maximum amount of voltage that the EV connector 206 permits to be delivered to the one or more batteries 210). The maximum SOC may be determined by determining how much energy will be used the next day based on the previous usage information plus X margin (e.g., average of prior use plus 1 or 2 standard deviations).

In step 406, the controller 212 determines the maximum SOC and/or battery capacity of the one or more batteries 210. In step 408, the controller 212 allows the EV connector 206 to deliver a maximum amount of voltage to the one or more batteries 210 to achieve a maximum SOC. Once the maximum SOC is achieved, the controller 212 may direct (e.g., deactivate) the EV connector 206 to stop delivering voltage to the one or more batteries 210. In an example, charging may cease. In another example, the EV connector 206 may direct any excess voltage to the other one or more charging components 208 such that no voltage is delivered to the one or more batteries 210. In an example, the one or more charging components 208 may direct the voltage to the power delivery system 40, thereby allowing the TRU 20 to operate while the charger 204 is connected.

Thermal loss in a refrigerated trailer may be a key metric in determining the life, usefulness, and energy requirements of the trailer. Thermal loss may take into account the insulative values of all components of the TRU 20 including the losses through the doors. Factors that affect thermal loss may include ambient temperature, internal temperature, insulative values of walls, floor, and roof (and the degradation of these insulative values over time), and door openings (including how long doors are open and the frequency at which they are opened).

Both the physical system (e.g., the trailer length, trailer height, insulative properties, and door type) and the operating conditions (e.g., temperature conditions, measured internal temperature and measured external temperature, and/or door openings) of the TRU 20 play a role in thermal loss. Door openings play a particularly large role in thermal loss. Door openings connect the interior cold air directly to the ambient air. If the TRU 20 is running it may pull in external air and heat. If the TRU 20 is not running, natural convection may be driving force for thermal loss.

Under constant operation conditions, thermal loss can be calculated based on a rate of heat gain/rise over time (i.e., temperature increase after hitting a set point and turning off system) or based on input thermal energy required to keep a constant temperature (i.e., TRU 20 input thermal energy). An initial standardized value of thermal loss for the trailer may be compared to a calculated value and validated over time.

To determine the battery capacity required in either of step 306 or step 406, the controller 212 converts an expected thermal energy loss (“TEL”) of the trailer over the duty cycle to electric power requirements of the TRU 40.

In embodiments of this invention, an initial Thermal Loss Quotient (TLQ) is estimated through an analysis of the available information about the system. The information that is used to calculate the estimate can include, without limitation, the trailer physical volume, the insulation thickness, the type of door (e.g., swing or roll up), expected cooling system coefficient of performance, and combinations thereof. These values create the estimate that can then be compared to actual measurements. To measure TLQ empirically there are two options: 1) measure heat rise over a period of time, and/or 2) measure input energy required to maintain a constant temperature. The measured TLQ is then compared to the estimated TLQ to create a baseline that can be tracked over time. The first option for measuring TLQ with heat rise requires a trailer to be empty, cooled to a temperature, then measure the heat rise internally compared to the ambient temperature over a period of time. This provides a unitized thermal loss over time give a temperature delta, if the trailer is loaded the load in the trailer has a thermal mass that may change TLQ. This first option relies on the estimated system coefficient of performance to provide the electrical energy required to generate the TLQ.

A second option for measuring the TLQ through constant input and constant temperature allows for operation with a loaded trailer. Again a known ambient temperature delta is use to compare thermal input to thermal loss; at a steady state the input and output thermal energy will be equal, even with a thermal mass inside the trailer. This second method includes the coefficient of performance, as the input energy being measured is the electrical energy. The TLQ is used to compare operating conditions over time; the TLQ will be different at different temperature deltas and different ambient and set point temperature. Additionally it can be used to identify operational inconsistencies, if the measured TLQ is dramatically off, it is possible that the doors were open. Over time TLQs are calculated as often as practicable which provides a TLQ data set for a given trailer and various operating conditions. The TLQ data set is the basis for the Thermal Expected Loss or TEL. With a data set created empirically or estimated initially for TLQs, a daily TEL can be predicted based on operating conditions.

The TEL is calculated based on the forecast temperatures for the next day, the expected operating temperature of the trailer load, the operating time, the TLQ for the conditions, and a safety factor. This TEL is an estimate of the battery capacity required or energy that will be required for the next day's energy use. This value is then sent to the fleet operator, battery BMS or battery charger to limit the maximum charge of the battery system or change the number of batteries on a system; the total energy needed as a percentage of total battery size is the maximum State of Charge (SOC). Alternatively the total energy required can be compared to the available battery capacity on the vehicle currently and additional battery modules can be added or removed to provide the total energy required.

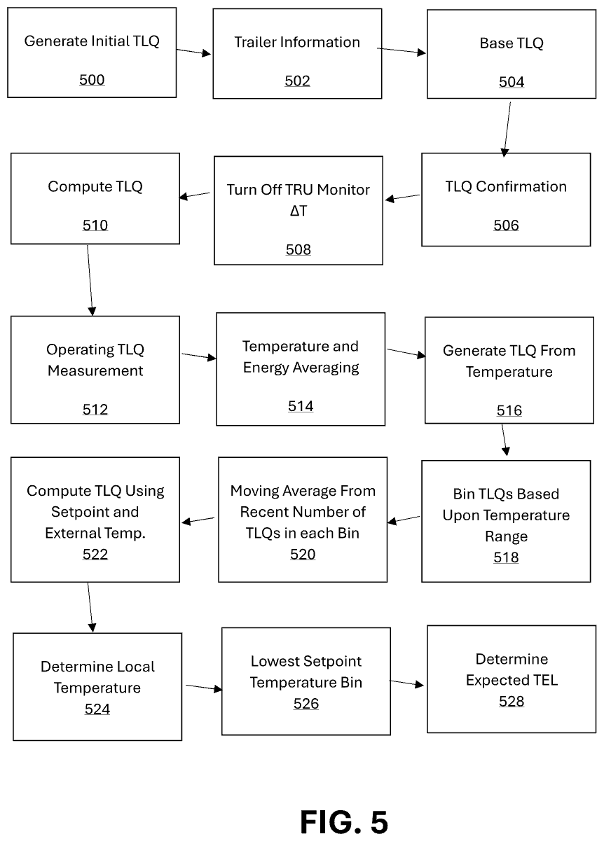

FIG. 5 shows an exemplary process for determining a TLQ of a transport trailer. There are two primary sets of variables, namely the physical system and the operating conditions. To generate an initial TLQ estimate (500) the physical system can be estimated (502) using the following inputs: trailer length, trailer height, insulation (thickness), and/or door type (swing or roll doors). To further improve the base TLQ (504), or because the physical system will degrade over time, the base TLQ (504) is confirmed (506) during operating conditions.

Two ways to calculate physical thermal loss in a constant operating condition are the heat gain/heat rise rate over time (508; temperature increase after hitting a set point, with system off) and input thermal energy required to keep a constant temperature (TRU input thermal energy). An initial value allows for validation through comparisons of calculated value (510). In embodiments, the TLQ can be considered as ambient temperature-internal temperature/time.

Steps 512 to 522 shows an operational TLQ measurement that can be additionally or alternatively used to confirm estimation. The internal transport temperature and the external temperature can be monitored, along with the input energy for the TRU. These measurements can be averaged over time (514) and used to generate or update the TLQ based upon external temperature (516). The result is a TLQ for each of various external temperatures. The TLQ based upon temperature can be grouped together (“Bins” 518) and used to obtain a moving average from the most recent number of TLQs in each bin (520). The final TLQ is computed from a set point and the external temperatures (522). From the local temperature (524) the lowest set point temperature bin is selected (526). The expected TEL (528) is then determined.

In some systems there may be onboard power generation systems that generate power during the operation of the system. These onboard power generation systems may include solar panels or a motor generator connected to an axle. The solar panels produce electrical power when the sun is shining on the system. The motor generator connected to an axle captures rotational energy and converts it into electricity. The addition of solar panels or a motor generator connected to an axle may enable further lowering of the maximum state of charge or removing battery modules to lower the total battery capacity. Similar to the forecasted temperature being used to estimate the TEL a forecast is required for estimating the amount of solar power that can be produced in the next day.

The NDS, Next Day Solar power produced is an estimation using historic solar power production, known production capacity, operating hours, next day forecast of temperature, solar radiation, and cloudiness. All solar power produced is measured, including amount, time of day, current weather conditions, and location. The operating of the system is also measured to determine if solar power is produced when the unit is away from the charging facility. If solar power is produced historically when away from the facility the NDS is calculated and subtracted from the TEL, reducing the battery capacity required and/or maximum state of charge.

The MGP, momentum generated power, is an estimation of how much power will be generated from the motor generator connected to an axle. The MGP is based on historical power generated during operations. MGP can provide significant power in some instances and could significantly reduce the need for battery charging and/or battery capacity required. Power can be generated from dragging or adding a load while in operation or generated during braking events. These options can create significantly different MGP values, though however configured, if no configuration is changed an average historical value for MGP can used for the next day MGP and battery capacity requirement and/or maximum state of charge.

Systems and methods of the present disclosure may include and/or may be implemented by one or more specialized computers including specialized hardware and/or software components. For purposes of this disclosure, a specialized computer may be a programmable machine capable of performing arithmetic and/or logical operations and specially programmed to perform the functions described herein. In some embodiments, computers may comprise processors, memories, data storage devices, and/or other commonly known or novel components. These components may be connected physically or through network or wireless links. Computers may also comprise software which may direct the operations of the aforementioned components. Computers may be referred to as servers, personal computers (PCs), mobile devices, and other terms for computing/communication devices. For purposes of this disclosure, those terms used herein are interchangeable, and any special purpose computer particularly configured for performing the described functions may be used.

Computers may be linked to one another via one or more networks. A network may be any plurality of completely or partially interconnected computers wherein some or all of the computers are able to communicate with one another. It will be understood by those of ordinary skill that connections between computers may be wired in some cases (e.g., via wired TCP connection or other wired connection) or may be wireless (e.g., via a WiFi network connection). Any connection through which at least two computers may exchange data can be the basis of a network. Furthermore, separate networks may be able to be interconnected such that one or more computers within one network may communicate with one or more computers in another network. In such a case, the plurality of separate networks may optionally be considered to be a single network.

The term “computer” shall refer to any electronic device or devices, including those having capabilities to be utilized in connection with an electronic information/transaction system, such as any device capable of receiving, transmitting, processing and/or using data and information. The computer may comprise a server, a processor, a microprocessor, a personal computer, such as a laptop, palm PC, desktop or workstation, a network server, a mainframe, an electronic wired or wireless device, such as for example, a telephone, a cellular telephone, a personal digital assistant, a smartphone, an interactive television, such as for example, a television adapted to be connected to the Internet or an electronic device adapted for use with a television, an electronic pager or any other computing and/or communication device.

The term “network” shall refer to any type of network or networks, including those capable of being utilized in connection with the systems and methods described herein, such as, for example, any public and/or private networks, including, for instance, the Internet, an intranet, or an extranet, any wired or wireless networks or combinations thereof.

The term “computer-readable storage medium” should be taken to include a single medium or multiple media that store one or more sets of instructions. The term “computer-readable storage medium” shall also be taken to include any medium that is capable of storing or encoding a set of instructions for execution by the machine and that causes the machine to perform any one or more of the methodologies of the present disclosure.

Referring now to FIG. 5, a functional block diagram of a machine in the example form of computer system 600 within which a set of instructions for causing the machine to perform any one or more of the methodologies, processes or functions discussed herein may be executed is shown. In some examples, the machine may be connected (e.g., networked) to other machines as described above. The machine may operate in the capacity of a server or a client machine in a client-server network environment, or as a peer machine in a peer-to-peer (or distributed) network environment. The machine may be any special-purpose machine capable of executing a set of instructions (sequential or otherwise) that specify actions to be taken by that machine for performing the functions described herein. Further, while only a single machine is illustrated, the term “machine” shall also be taken to include any collection of machines that individually or jointly execute a set (or multiple sets) of instructions to perform any one or more of the methodologies discussed herein. In some examples, one or more components of FIG. 2, including the controller 212 may be implemented by a specialized machine, particularly programmed to perform certain functions, such as the example machine shown in FIG. 5 (or a combination of two or more of such machines).

Example computer system 600 may include processing device 602, memory 606, data storage device 510 and communication interface 512, which may communicate with each other via data and control bus 518. In some examples, computer system 600 may also include display device 514 and/or user interface 516.

Processing device 602 may include, without being limited to, a microprocessor, a central processing unit, an application-specific integrated circuit (ASIC), a field programmable gate array (FPGA), a digital signal processor (DSP) and/or a network processor. Processing device 602 may be configured to execute processing logic 604 for performing the operations described herein. Processing device 602 may include a special-purpose processing device specially programmed with processing logic 604 to perform the operations described herein.

Memory 606 may include, for example, without being limited to, at least one of a read-only memory (ROM), a random access memory (RAM), a flash memory, a dynamic RAM (DRAM) and a static RAM (SRAM), storing computer-readable instructions 608 executable by processing device 602. Memory 606 may include a non-transitory computer readable storage medium storing computer-readable instructions 608 executable by processing device 602 for performing the operations described herein. For example, computer-readable instructions 608 may include operations performed by the controller 212, including operations shown in FIGS. 3 and 4. Although one memory device 606 is illustrated in FIG. 5, in some examples, computer system 600 may include two or more memory devices (e.g., dynamic memory and static memory).

Computer system 600 may include communication interface device 512, for direct communication with other computers (including wired and/or wireless communication) and/or for communication with a network. In some examples, computer system 600 may include display device 514 (e.g., a liquid crystal display (LCD), a touch sensitive display, etc.). In some examples, computer system 600 may include user interface 516 (e.g., an alphanumeric input device, a cursor control device, etc.).

In some examples, computer system 600 may include data storage device 510 storing instructions (e.g., software) for performing any one or more of the functions described herein. Data storage device 510 may include a non-transitory computer-readable storage medium, including, without being limited to, solid-state memories, optical media and magnetic media.

The methods described herein, including those with reference to one or more flowcharts, may be performed by a controller and/or processing device (e.g., smartphone, computer, etc.). The methods may include one or more operations, functions, or actions as illustrated in one or more of blocks. Although the blocks are illustrated in sequential order, these blocks may also be performed in parallel, and/or in a different order than the order disclosed and described herein. Also, the various blocks may be combined into fewer blocks, divided into additional blocks, and/or removed based upon a desired implementation. Dashed lines may represent optional and/or alternative steps.

Additional examples of the presently described method and device embodiments are suggested according to the structures and techniques described herein. Other non-limiting examples may be configured to operate separately or may be combined in any permutation or combination with any one or more of the other examples provided above or throughout the present disclosure. Components and/or arrangement of components illustrated in one figure may be incorporated into any other figure.

It will be appreciated by those skilled in the art that the present disclosure may be embodied in other specific forms without departing from the spirit or essential characteristics thereof. The presently disclosed embodiments are therefore considered in all respects to be illustrative and not restricted. The scope of the disclosure is indicated by the appended claims rather than the foregoing description and all changes that come within the meaning and range and equivalence thereof are intended to be embraced therein.

In general, terminology may be understood at least in part from usage in context. For example, terms, such as “and”, “or”, or “and/or,” as used herein may include a variety of meanings that may depend at least in part upon the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

The terms “including” and “comprising” should be interpreted as meaning “including, but not limited to.” If not already set forth explicitly in the claims, the term “a” should be interpreted as “at least one” and the terms “the, said, etc.” should be interpreted as “the at least one, said at least one, etc.”

The present disclosure is described with reference to block diagrams and operational illustrations of methods and devices. It is understood that each block of the block diagrams or operational illustrations, and combinations of blocks in the block diagrams or operational illustrations, may be implemented by means of analog or digital hardware and computer program instructions. These computer program instructions may be provided to a processor of a general purpose computer to alter its function as detailed herein, a special purpose computer, ASIC, or other programmable data processing apparatus, such that the instructions, which execute via the processor of the computer or other programmable data processing apparatus, implement the functions/acts specified in the block diagrams or operational block or blocks. In some alternate implementations, the functions/acts noted in the blocks may occur out of the order noted in the operational illustrations. For example, two blocks shown in succession may be executed substantially concurrently or the blocks may sometimes be executed in the reverse order, depending upon the functionality/acts involved.

For the purposes of this disclosure a non-transitory computer readable medium (or computer-readable storage medium/media) stores computer data, which data may include computer program code (or computer-executable instructions) that is executable by a computer, in machine readable form. By way of example, and not limitation, a computer readable medium may comprise computer readable storage media, for tangible or fixed storage of data, or communication media for transient interpretation of code-containing signals. Computer readable storage media, as used herein, refers to physical or tangible storage (as opposed to signals) and includes without limitation volatile and non-volatile, removable and non-removable media implemented in any method or technology for the tangible storage of information such as computer-readable instructions, data structures, program modules or other data. Computer readable storage media includes, but is not limited to, RAM, ROM, EPROM, EEPROM, flash memory or other solid state memory technology, CD-ROM, DVD, or other optical storage, cloud storage, magnetic cassettes, magnetic tape, magnetic disk storage or other magnetic storage devices, or any other physical or material medium which may be used to tangibly store the desired information or data or instructions and which may be accessed by a computer or processor.

A computing device may be capable of sending or receiving signals, such as via a wired or wireless network, or may be capable of processing or storing signals, such as in memory as physical memory states, and may, therefore, operate as a server. Thus, devices capable of operating as a server may include, as examples, dedicated rack-mounted servers, desktop computers, laptop computers, set top boxes, integrated devices combining various features, such as two or more features of the foregoing devices, or the like.

It is the Applicant's intent that only claims that include the express language “means for” or “step for” be interpreted under 35 U.S.C. 112 (f). Claims that do not expressly include the phrase “means for” or “step for” are not to be interpreted under 35 U.S.C. 112 (f).

What is claimed is:

1. A method of charging a battery system for a transport refrigeration unit (“TRU”) installed on a transport, the method comprising:
determining a location and/or a travel route for the TRU;
analyzing a weather pattern for the location and/or the travel route to determine an expected environment;
determining a maximum state of charge for the battery system as a function of the expected environment; and
charging the battery system with a power supply to obtain the maximum state of charge.

2. The method of claim 1, wherein the maximum state of charge is determined as a function of a time at the location and/or the travel before reaching a next power supply.

3. The method of claim 1, further comprising downloading the weather pattern as forecast data from a weather service.

4. The method of claim 1, wherein the maximum state of charge is determined by comparing the weather pattern to historical weather patterns and battery use for the TRU.

5. The method of claim 1, further comprising:
determining a thermal loss quotient for the transport; and
determining the maximum state of charge for the battery system as a function of the expected environment and the thermal loss quotient.

6. The method of claim 5, wherein the thermal loss quotient is determined from a cooling system coefficient of performance and/or transport information selected from transport volume, transport insulation value, and transport door type.

7. The method of claim 5, further comprising:
establishing a baseline thermal loss quotient for the transport;
determining a cooling efficiency of the TRU over time; and
adjusting the baseline thermal loss quotient based upon the determined cooling efficiency.

8. The method of claim 1, further comprising determining an expected power generation by an onboard vehicle power system, and adjusting the maximum state of charge for the expected power generation.

9. The method of claim 1, wherein the power supply connects to the battery system using an electric vehicle charger, and further comprising operating TRU components with the power supply after reaching to the maximum state of charge and the electric vehicle charger is still connected.

10. The method of claim 1, further comprising determining a required battery capacity and adding or removing a battery in the battery system.

11. A method of charging a battery system for a transport refrigeration unit (“TRU”) of a transport, the method comprising:
determining a thermal loss quotient for the TRU;
analyzing a weather pattern for a location and/or a travel route to determine an expected environment for the transport;
determining a maximum state of charge for the battery system as a function of the thermal loss quotient and the expected environment; and
charging the battery system with a power supply to obtain the maximum state of charge.

12. The method of claim 11, wherein the thermal loss quotient is determined from heat rise over a period of time and/or energy input required to maintain a steady transport temperature.

13. The method of claim 11, further comprising determining the maximum state of charge as a function of a transport temperature need and estimated operation time.

14. The method of claim 11, wherein the maximum state of charge is determined for a 6-16 hour operation period.

15. A power system for a transport refrigeration unit (“TRU”) installed on a transport, the power system comprising:
at least one battery;
a charging connector in electrical supply combination with the at least one battery;
a controller in combination with the charging connector and configured to control a charge level of the at least one battery, wherein:
the controller comprises a network connection adapted to connect with transport systems and external weather data, and the controller is configured to determine a location and/or a travel route for the TRU, analyze a weather pattern for the location and/or the travel route to determine an expected environment, determine a maximum state of charge for the battery system as a function of the expected environment, and charge the at least one battery via the charging connector to obtain the maximum state of charge.

16. The system of claim 15, wherein the maximum state of charge is determined as a function of a time at the location and/or the travel before reaching a next power supply.

17. The system of claim 15, wherein the controller automatically downloads forecast data from a weather service.

18. The system of claim 15, wherein the maximum state of charge is determined by comparing the weather pattern to historical weather patterns and battery use for the TRU.

19. The system of claim 15, wherein the controller comprises a predetermined thermal loss quotient for the transport, and determines the maximum state of charge for the battery system as a function of the expected environment and the thermal loss quotient.

20. The system of claim 15, wherein the controller determines a required battery capacity and notifies an operator to add or remove a battery in the battery system as a function of the required battery capacity.
